(19) United States
(12) Patent Application Publication
(10) Pub. No.: US 2018/0248547 A1
(43) Pub. Date: Aug. 30, 2018

(54) CAPACITIVE TOUCH SWITCH, CONFIGURATION OF CAPACITIVE TOUCH SWITCHES AND OPERATING DEVICE

(71) Applicant: DIEHL AKO STIFTUNG & CO. KG, WANGEN (DE)

(72) Inventor: PAWEL MASINA, ZLOCZEW (PL)

(21) Appl. No.: 15/966,094

(22) Filed: Apr. 30, 2018

Related U.S. Application Data
(63) Continuation of application No. PCT/EP2015/002184, filed on Oct. 30, 2015.

(51) Int. Cl. H03K 17/96; G06F 3/044

(52) U.S. Cl. CPC H03K 17/9622; G06F 3/044

(57) ABSTRACT

A capacitive touch switch for an operating device of an electronic domestic appliance has an at least partly translucent cover plate with a user side facing a user, a carrier plate disposed on a side of the cover plate facing away from the user side at a distance therefrom, and a light source mounted on the carrier plate. A sensor plate is disposed between the cover plate and the carrier plate and has an at least partly translucent substrate and a sensor layer of an electrically conductive material. The sensor layer has a sensor region of the electrically conductive material forming a sensor electrode and a symbol region without the electrically conductive material forming a symbol that can be backlit by the light source. A configuration of a plurality of capacitive touch switches and an operating device, are also provided.

### CROSS-REFERENCE TO RELATED APPLICATION

This is a continuation application, under 35 U.S.C. § 120, of copending International Application PCT/EP2015/002184, filed Oct. 30, 2015, which designated the United States.

### BACKGROUND OF THE INVENTION

### Field of the Invention

The present invention relates to a capacitive touch switch, in particular a capacitive touch switch for an operating device of an electronic domestic appliance. The present invention also relates to a configuration of capacitive touch switches and an operating device.

In many electric or electronic appliances, in particular including domestic appliances such as cookers, cooktops, microwave ovens, dishwashers, laundry appliances, refrigerators and/or freezers and the like, touch-sensitive and/or proximity-sensitive pushbutton switches (i.e. touch switches in the sense of the present invention), which can be actuated by a simple touch or approach by a user or a finger of a user, are used more and more frequently.

In the case of a capacitive touch switch, a capacitive sensor element together with a finger of a user, for example, acting through a cover as a dielectric in between, forms a capacitor which has a variable capacitance in accordance with the touching or non-touching of a touch field of the cover assigned to the capacitive sensor element. The variation in the capacitance acts in a corresponding way on an output signal of the sensor circuit connected to the capacitive sensor element, which signal can be interpreted by evaluation electronics, if appropriate as an actuation of the touch switch.

European Patent Application EP 1 257 057 A1, corresponding to U.S. Pat. No. 6,664,489, discloses a capacitive touch switch in which the capacitive sensor element rests on the underside of the cover, facing away from the user, and is configured to be partly translucent for the display of a symbol, so that it can be backlit by a light source on a carrier plate.

German Patent Application DE 103 26 684 A1, corresponding to U.S. Pat. No. 7,507,929, discloses a capacitive touch switch having a capacitive sensor element, which is clamped in between the cover and a fiber optic element and includes a transparent carrier film with an ITO coating. If required, symbols can be created by additional printing or masks on the fiber optic element or the sensor element.

European Patent EP 1 894 712 B1 describes a capacitive touch switch which has a multilayer film behind a cover made of glass, wherein the film has a first carrier layer printed with a conductive layer and a second carrier layer printed with a colored layer. The carrier layers are connected to each other and to the cover by adhesive layers. In addition, translucent pictograms can be formed in the conductive layer on the first carrier layer.

### SUMMARY OF THE INVENTION

It is accordingly an object of the invention to provide a capacitive touch switch, a configuration of capacitive touch switches and an operating device, which overcome the hereinafore-mentioned disadvantages of the heretofore-known devices of this general type and which provide an improved capacitive touch switch with a simple structure, which is heat-resistant and permits backlit symbols.

With the foregoing and other objects in view there is provided, in accordance with the invention, a capacitive touch switch including an at least partly translucent cover plate with a user side facing a user; a carrier plate, which is disposed on a side of the cover plate facing away from the user side, at a distance therefrom; a light source, which is mounted on the carrier plate; a sensor plate, which is disposed between the cover plate and the carrier plate and has an at least partly translucent substrate and a sensor layer of an electrically conductive material, wherein the sensor layer has a sensor region of the electrically conductive material to form a sensor electrode, and a symbol region without the electrically conductive material to form a symbol that can be backlit by the light source.

According to the invention, it is proposed to use a multifunctional sensor plate which, firstly, provides the capacitive sensor element and at the same time the symbol that can be backlit in only one component. As a result of this measure, the number of individual components is reduced, so that the structure and assembly of the touch switch can be simplified. As a result of the use of a sensor plate with a dimensionally stable substrate, a greater heat resistance of the capacitive touch switch can additionally be achieved in comparison with the use of sensor films.

A printed circuit board (PCB) having a layer thickness of at most 1.2 mm is preferably used for the substrate of the sensor plate. Standard printed circuit boards with a layer thickness of 1.0 mm or 0.6 mm can preferably be used. These printed circuit boards are firstly dimensionally stable and heat-resistant and secondly are translucent because of the low layer thickness.

One or more light-emitting diodes (LEDs) are preferably used for the light source.

A printed circuit board (PCB) is preferably used for the carrier plate. Standard printed circuit boards with a layer thickness of 1.5 mm can preferably be used. The evaluation electronics for processing and evaluating the output signals generated by the sensor circuit are preferably also provided on the carrier plate. The control system, for example of the domestic appliance, to which the evaluation electronics are connected and which can optionally likewise be disposed on the carrier plate or at another location in the domestic appliance, is to be distinguished from these evaluation electronics.

The cover plate is preferably a plate-like body of an at least partly translucent material (e.g. glass, glass ceramic, plastic, etc). In addition, the cover plate is preferably made of an electrically non-conductive or insulating material.

The symbol region is preferably formed within the sensor region of the sensor layer.

In addition, the sensor region of the sensor layer is preferably surrounded by an intermediate region without the electrically conductive material.

In an advantageous refinement of the invention, the sensor layer is a layer of the electrically conductive material (e.g. copper) which is deposited on the substrate and in which the symbol region and/or the intermediate region are formed by using etching technology. Thus, the entire sensor plate can be made by using conventional production and processing techniques of printed circuit boards.

The sensor plate can optionally contain one or two sensor layers. Thus, the sensor plate preferably can have a first sensor layer on a side of the substrate facing the cover plate and/or a second sensor layer on a side of the substrate facing the carrier plate.

In an advantageous refinement of the invention, a diffusion layer is also provided on a side of the sensor plate facing the cover plate and/or on a side of the sensor plate facing the carrier plate. This diffusion layer is preferably applied by using screen printing (silk screen). In addition, the diffusion layer is preferably applied to a side of the sensor layer(s) of the sensor plate that faces away from the substrate. The diffusion layer is intended in particular to effect more uniform illumination of the symbol formed by the symbol region. The diffusion layer preferably forms part of the sensor plate.

In a preferred alternative, the diffusion layer is formed in such a way that it suppresses optical crosstalk. In optically inactive regions, the diffusion layer formed as a crosstalk-avoiding layer shields the cover plate from the light source.

In a further advantageous refinement of the invention, the sensor plate is connected to the cover plate by an at least partly translucent adhesive layer. Alternatively, the sensor plate can also rest directly on the cover plate.

In an analogous way, the sensor plate can also be connected to the carrier plate by an adhesive layer or rest directly on the carrier plate.

In still a further advantageous refinement of the invention, a frame element having an opaque separating region which surrounds the light source circumferentially on the carrier plate can be provided on a side of the carrier plate that faces the cover plate. The frame element preferably forms part of the carrier plate. Through the use of the frame element, the light emitted by the light source can be led more efficiently to the symbol region of the sensor plate and/or the symbol region can be shielded against ambient light, extraneous light, etc.

With the objects of the invention in view, there is also provided a configuration including a plurality (i.e. at least two) of the above-described capacitive touch switches of the invention. The plurality of touch switches of the configuration then preferably use a common cover plate, a common carrier plate and a common sensor plate.

With the objects of the invention in view, there is concomitantly provided an operating device, in particular for an electronic domestic appliance, having at least one above-described capacitive touch switch of the invention.

Other features which are considered as characteristic for the invention are set forth in the appended claims.

Although the invention is illustrated and described herein as embodied in a capacitive touch switch, a configuration of capacitive touch switches and an operating device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, sectional view of a configuration of capacitive touch switches according to the invention in an exploded illustration; and

FIG. 2 is a sectional view of a sensor plate of the configuration of touch switches of FIG. 1 according to an exemplary embodiment of the invention.

### DETAILED DESCRIPTION OF THE INVENTION

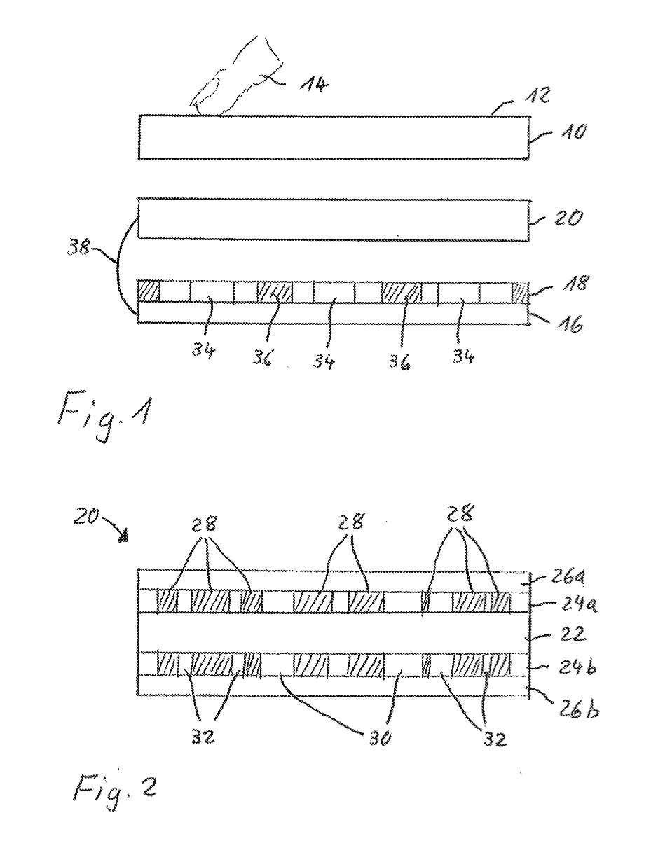

Referring now to FIGS. 1 and 2 of the drawings in detail, there is seen an exemplary embodiment of a configuration of a plurality of capacitive touch switches (i.e. touch-sensitive and/or proximity-sensitive pushbutton switches), as can be used advantageously in an operating device of an electronic domestic appliance, such as a cooktop or a cooker.

The configuration of FIG. 1 contains, by way of example, three capacitive touch switches, which use some components jointly. For the purpose of a simpler formulation, the structure of one of these touch switches will be described first below, it being clear to those skilled in the art that all the touch switches are constructed analogously to one another.

The touch switch contains a cover plate 10, for example formed of glass, which is at least partly translucent. On a user side 12 (at the top in FIG. 1) facing a user 14, the cover plate 10 defines a touch area which actuates the touch switch when touched or approached by the user.

On a side of the cover plate 10 that faces away from the user side 12, a carrier plate 16 is disposed at a distance from the user side 12. The carrier plate 16 is, for example, a printed circuit board (PCB) with a layer thickness of about 1.5 mm. In particular, electronic components of a sensor circuit and an evaluation circuit for the touch switch are mounted on the carrier plate 16. As is illustrated in FIG. 1, the touch switch additionally contains a light source 34, which is mounted on the carrier plate 16. The light source 34 is, for example, one or more light-emitting diodes (LEDs).

In addition, a frame element 18 is provided on the side of the carrier plate 16 facing the cover plate 10. This frame element 18 contains an opaque separating region 36, which surrounds the light source 34 circumferentially. The frame element 18 therefore shields the light source 34 against the surroundings and against light sources of adjacent touch switches. The carrier plate 16 and the frame element 18 preferably form an integral or one-piece component.

A sensor plate 20 is additionally disposed between the cover plate 10 and the carrier plate 16. This sensor plate 20 can rest directly on the cover plate 10 or be connected to the cover plate 10 by an at least partly translucent adhesive layer. In addition, the sensor plate 20 can rest directly on the carrier plate 16 or be connected to the carrier plate 16 by an adhesive layer.

The structure of the sensor plate is illustrated in more detail in FIG. 2.

The sensor plate 20 has in particular a substrate 22. The substrate preferably includes a printed circuit board (PCB) having a layer thickness of, for example, 0.6 mm or 1.2 mm. Due to this low layer thickness, the substrate is dimensionally stable and heat-resistant (for temperatures of 100° C., 120° C. and more) but nevertheless is at least partly translucent.

On a side of the substrate 22 that faces the cover plate 10 (at the top in FIG. 2), the sensor plate 20 has a sensor layer 24a of an electrically conductive material such as, for example, copper. The copper layer can be deposited on the substrate 22 in a standard process.

Through the use of a standard etching process, sensor regions 28 of copper are formed in this sensor layer 24a and are surrounded by intermediate regions 30 without copper. These sensor regions 28 form the capacitive sensor elements of the capacitive touch switch which form a capacitor using the cover plate 10 acting as a dielectric and the finger of the user 14. The sensor regions 28 of the sensor plate 20 are connected to the sensor circuits and the evaluation electronics on the carrier plate 16 through an electrically conductive connection 38 (see FIG. 1).

Through the use of a further standard etching process, symbol regions 32 without copper are additionally formed in the sensor regions 28 of copper. These symbol regions 32 represent pictograms, symbols, numbers, letters, etc, which are translucent and can thus be backlit with the aid of the light source 34. One or more symbol regions 32 can be formed in a sensor region 28.

The sensor plate 20 is thus a component which forms both the capacitive sensor elements in the form of the sensor regions 28 of copper and the information or decoration elements that can be backlit and are available in the form of the symbol regions 32. For this purpose, the substrate 22 of the sensor plate 20 must be at least partly translucent, which can be achieved by an appropriately low layer thickness of the printed circuit board. As a result of the use of a printed circuit board as the substrate 22, the sensor plate 20 is additionally sufficiently dimensionally stable and heat-resistant, so that the capacitive touch switch can also be used in rougher environments.

As is illustrated in FIG. 2, a diffusion layer 26a is also optionally provided on the side of the sensor layer 24a that faces the cover plate 10. This diffusion layer 26a is, for example, produced in the form of a screen print (silk screen) and is intended to effect a more uniformly illuminated appearance of the symbol of the symbol region 32.

As is indicated in FIG. 2, the sensor plate 20 can optionally have a further sensor layer 24b on the side of the substrate 22 facing the carrier plate 16 (at the bottom in FIG. 2) and/or a further diffusion layer 26b on the side of the sensor plate 20 facing the carrier plate 16. This further sensor layer 24a and this further diffusion layer 26b can be provided additionally or alternatively to the sensor layer 24a and can be respectively provided in addition to the diffusion layer 26a.

If the diffusion layer 26a, 26b is formed as a crosstalk-avoiding layer, it suppresses optical crosstalk. In an optically inactive region, the crosstalk-avoiding layer shields the cover plate 10 from the light source and, in this region, avoids transillumination of the cover plate 10. If the crosstalk-avoiding layer is interrupted, transillumination of the cover plate 10 is possible in the region of this interruption; this region is optically active, for example in the symbol region 32.

The entire sensor plate 20 is preferably provided as an integral or one-piece component.

The following is a summary list of reference numerals and the corresponding structure used in the above description of the invention:

### LIST OF REFERENCE NUMBERS

10 Cover plate
12 User side
14 User, finger
16 Carrier plate
18 Frame element
20 Sensor plate
22 Substrate
24a, 24b Sensor layer
26a, 26b Diffusion layer
28 Sensor region
30 Intermediate region
32 Symbol region
34 Light source
36 Separating region
38 Electrically conductive connection

1. A capacitive touch switch, comprising:
an at least partly translucent cover plate having a user side facing a user and a side facing away from said user side;
a carrier plate disposed at said side of said cover plate facing away from said user side and disposed at a distance from said side of said cover plate facing away from said user side;
a light source mounted on said carrier plate; and
a sensor plate disposed between said cover plate and said carrier plate, said sensor plate having an at least partly translucent substrate and a sensor layer formed of an electrically conductive material;
said sensor layer having a sensor region formed of said electrically conductive material, said sensor region forming a sensor electrode and a symbol region without said electrically conductive material forming a symbol to be backlit by said light source.

2. The capacitive touch switch according to claim 1, wherein said substrate of said sensor plate is a printed circuit board with a layer thickness of at most 1.2 mm.

3. The capacitive touch switch according to claim 1, wherein said symbol region is formed within said sensor region of said sensor layer.

4. The capacitive touch switch according to claim 1, which further comprises an intermediate region without said electrically conductive material, said sensor region of said sensor layer being surrounded by said intermediate region.

5. The capacitive touch switch according to claim 1, wherein said sensor layer is a layer of said electrically conductive material deposited on said substrate, at least one of said symbol region or said intermediate region being etched in said sensor layer.

6. The capacitive touch switch according to claim 1, wherein:
said substrate has a side facing said cover plate and a side facing said carrier plate; and
said sensor plate has at least one of a first sensor layer disposed on said side of said substrate facing said cover plate or a second sensor layer disposed on said side of said substrate facing said carrier plate.

7. The capacitive touch switch according to claim 1, wherein:
said sensor plate has a side facing said cover plate and a side facing said carrier plate; and
a diffusion layer is provided on at least one of said side of said sensor plate facing said cover plate or said side of said sensor plate facing said carrier plate.

8. The capacitive touch switch according to claim 1, which further comprises an at least partly translucent adhesive layer connecting said sensor plate to said cover plate.

9. The capacitive touch switch according to claim 1, wherein:
said carrier plate has a side facing said cover plate; and
a frame element has an opaque separating region disposed on said side of said carrier plate facing said cover plate, said opaque separating region surrounding said light source circumferentially on said carrier plate.

10. A configuration, comprising:
a plurality of capacitive touch switches according to claim 1;
said cover plate, said carrier plate and said sensor plate being part of each of said plurality of capacitive touch switches.

11. An operating device for an electronic domestic appliance, comprising:
at least one capacitive touch switch according to claim 1.
